(19) United States
(12) Patent Application Publication
(10) Pub. No.: US 2025/0202470 A1
(43) Pub. Date: Jun. 19, 2025

(54) LINEAR OUTPUT DRIVER ARCHITECTURE FOR OPTICAL MODULATORS

(71) Applicant: Cisco Technology, Inc., San Jose, CA (US)

(72) Inventors: Kadaba Lakshmikumar, Hillsborough, NJ (US); Romesh Kumar Nandwana, Chapel Hill, NC (US); Alexander C. Kurylak, Nazareth, PA (US); Bibhu Prasad Das, Philadelphia, PA (US); Abhishek Bhat, Allentown, PA (US)

(21) Appl. No.: 18/539,389

(22) Filed: Dec. 14, 2023

(51) Int. Cl. H03K 17/06; H03K 17/16; H03K 17/687; H03K 19/003; H03K 19/0185

(52) U.S. Cl. CPC H03K 17/063; H03K 17/162; H03K 17/6871; H03K 19/00361; H03K 19/018514

(57) ABSTRACT

A driver circuit topology to drive a capacitive load, such as a semiconductor-insulator-semiconductor capacitor (SISCAP)-type capacitive load, in a linear fashion. The topology includes a combination of a pre-driver and output driver, the latter of which may also be referred to as an output stage. An open-loop (meaning without a feedback loop) class-AB push-pull transistor configuration is provided in the output stage to drive the capacitive load.

### TECHNICAL FIELD

The present disclosure relates to driver circuitry for optical equipment.

### BACKGROUND

In optical network equipment, an analog signal from a host device is used to drive an optical modulator that outputs a modulated optical signal to be transported via an optical fiber, for example. To achieve acceptable performance, the circuitry that drives the optical modulator should have certain characteristics, not the least of which is high linearity, particularly when the optical modulator operates as a capacitance load.

### BRIEF DESCRIPTION OF THE DRAWINGS

FIG. 1 illustrates a block diagram of an optical transceiver system in which linear driver circuit topologies presented herein may be employed, according to an example embodiment.

FIG. 2 is a block diagram of a transmit path of an optical transceiver system comprising a linear driver, according to an example embodiment.

FIG. 3 is a schematic diagram of a transmit path of an optical transceiver system including a linear driver comprising a pre-driver circuit and a output driver circuit, according to an example embodiment.

FIG. 4 is a schematic diagram of output driver circuit that is employs alternating current (AC)-coupling between the output of the pre-driver circuit and the input of the output driver circuit, according to an example embodiment.

FIG. 5 is a schematic diagram of a linear driver in which the output of the pre-driver circuit is direct current (DC)-coupled to the input of the output driver circuit, according to an example embodiment.

FIG. 6 is a schematic diagram of a linear driver in which the output of the pre-driver circuit is asymmetrically coupled (with AC-coupling and DC-coupling) to the input of the output driver circuit, according to an example embodiment.

### DESCRIPTION OF EXAMPLE EMBODIMENTS

### Overview

Briefly, driver circuit topologies are presented herein to drive a capacitive load, such as a semiconductor-insulator-semiconductor capacitor (SISCAP)-type capacitive load, in a linear fashion. The topologies include a combination of a pre-driver and output driver, the latter of which may also be referred to as an output stage. An open-loop (meaning without a feedback loop) class-AB push-pull transistor configuration is provided in the output stage to drive the capacitive load.

In one form, an linear driver apparatus is provided. The linear driver apparatus comprises a pre-driver circuit and an output driver circuit. The pre-driver circuit is configured to receive an analog input signal and amplify the analog input signal to generate at an output a pre-driver output signal. The output driver circuit has an input coupled to the output of the pre-driver circuit, and comprises a first transistor and a second transistor connected in a common-drain class-AB push-pull configuration. The output driver circuit generates from the pre-driver output signal a driver output signal to drive a capacitive load, wherein the first transistor and the second transistor are part of a translinear loop.

### Example Embodiments

Linear-driven optical modulators, such as Mach-Zehnder Interferometers (MZI) modulators, in optical network equipment have the advantage of avoiding the need for retimers for electro-optical links. However, even electro-optics links that use retimers can benefit from a linear driver.

Presented herein are embodiments for linear driver circuitry topologies for driving an optical modulator, such as an MZI modulator. The linear driver circuit topologies achieve a moderate voltage gain, large power gain, high bandwidth, large voltage swing, high linearity and high efficiency. The linear driver circuit topologies presented herein may be used in either a lumped or distributed environment (e.g., MZI modulators that are relatively long and the capacitance of the driver circuitry can be absorbed into a transmission line).

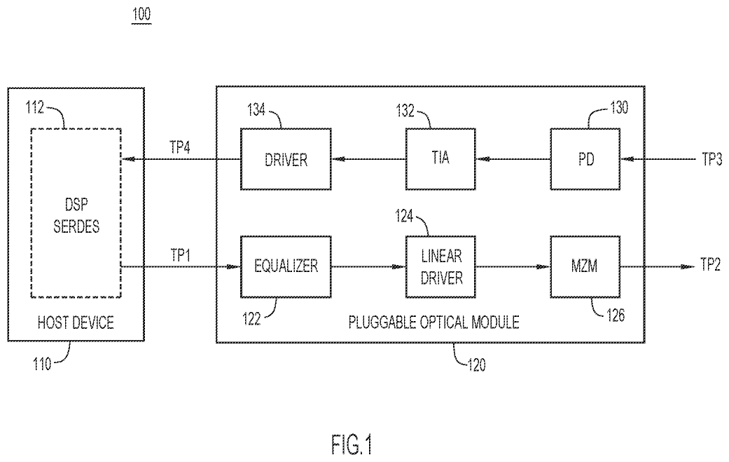

FIG. 1 illustrates a block diagram of a system 100 in which the linear driver circuit topologies presented herein may be employed. The system 100 includes a host device 110 and a pluggable optical module 120. The host device 110 includes a digital signal processor (DSP) serializer/deserializer (SERDES) 112 that outputs transmit (TX) data to the optical module 120 and obtains received (RX) data from the optical module 120.

The optical module 120 is configured as a “direct-drive” optical module in which there is no need for a serializer/deserializer (SERDES) digital signal processor in the optical module 120. That is, the optical module includes, in the transmit path, an equalizer 122, a linear driver 124 and a MZI modulator (MZM) 126. Though not shown as such, the output of the MZM 126 is coupled to an optical fiber. As described further below, the linear driver 124 is a high-swing highly linear electrical-to-optical (E/O) driver that is useful to drive a capacitive load, such as a semiconductor-insulator-semiconductor capacitor (SISCAP)-type capacitive MZM 126. The linear driver 124 also enables a (DSP) SERDES in the optical module 120 to be deleted. The linear driver 124 can also enable eliminating an extra short reach (XSR) clock and data recover (CDR) block in an optical transmit path of an optical module.

In the receive path, the optical module 120 includes a photodetector (PD) 130, a transimpedance amplifier (TIA) 132 and a driver 134.

A linear driver, such as linear driver 124, should have certain characteristics when driving MZM 126. The extinction ratio (ER) of an MZM is proportional to the product of the voltage swing (V) and the capacitance (C) of the MZM: ER α V*C. Thus, a high ER involves a large voltage swing and/or large capacitance. A large capacitance value C limits the bandwidth of the driver. A large voltage swing is limited by driver linearity and supply voltage.

While negative feedback can be used in lower frequency circuits to help maintain linearity, it is not useful in higher frequency circuits for high-bandwidth applications. That is, negative feedback cannot be used to improve linearity for high-bandwidth applications due to the bandwidth-limiting impact of negative feedback. The topology of the linear driver 124 should be inherently linear.

Class-AB push-pull output stages are used in traditional operational-amplifier (op-amp) designs. However, for broadband applications where negative feedback cannot be used, the challenge is to symmetrically drive the output transistors of the push-pull output stage while accounting for parasitic poles at very high frequencies. Thus, different coupling mechanisms are presented herein for driving a MZI modulator so that the bandwidth is determined by the load and not impacted by the parasitic poles.

A common-drain class-AB output stage topology has several advantages. There is no signal phase inversion between the input and the output, and the voltage gain is close to 1. There is no Miller-multiplication of input-output capacitance that limits bandwidth as in common-source designs (like a transconductance/transconductance (gm/gm) design). The linear output amplitude is limited to approximately one threshold voltage of the transistors (Vth), whereas in a common-source design it is limited to approximately Vth/2 (for unity voltage gain). The non-linearity of the source-follower driver transconductance (gm) is canceled by the non-linearity of the load (1/gm), resulting in excellent overall linearity.

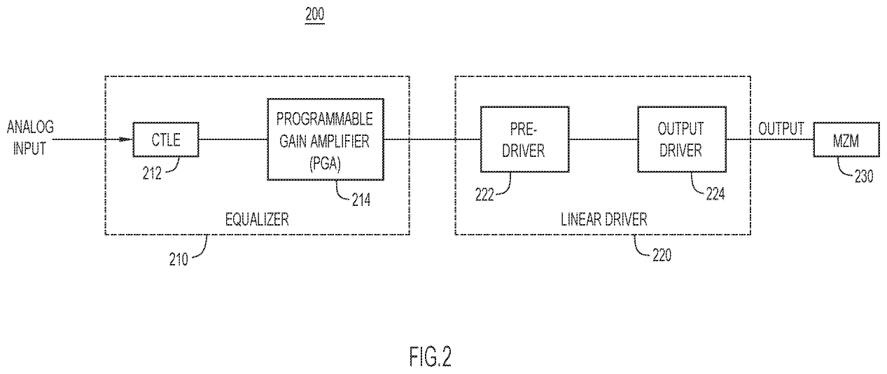

Referring now to FIG. 2, a block diagram is shown of an apparatus 200 that may be used in the transmit path of an optical module, such as the optical module 120 shown in FIG. 1. The apparatus 200 includes an equalizer 210 and a linear driver 220. The equalizer 210 may comprise a continuous time linear equalizer (CTLE) 212 and a programmable gain amplifier (PGA) 214. The linear driver 220 may comprise a pre-driver circuit 222 and a output driver circuit 224. The output driver circuit 224 may be also referred to as an output stage, output circuit or driver circuit. The output of the linear driver 220 is connected to an MZM 230.

A topology is presented herein for linear driver 220 to drive a SISCAP-type capacitive load, such as a MZI modulator, in a linear fashion. The linear driver 220 has a topology that combines the pre-driver circuit 222 and the output driver circuit 224. Several embodiments are provided for the coupling of the pre-driver circuit 222 to the output driver circuit 224 with different voltage supply, power, and linearity tradeoffs.

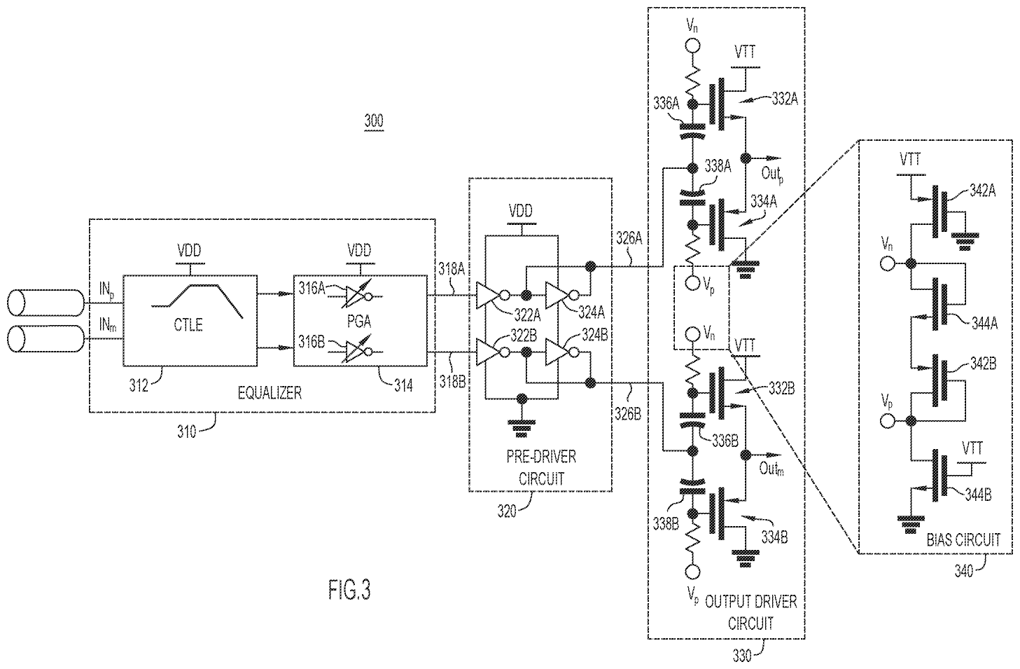

Turning now to FIG. 3, a schematic diagram is shown of an apparatus 300 that may be used in the transmit path of an optical module, according to an example embodiment. In this example, the apparatus 300 has differential signal paths, though the techniques presented herein may be used in a single-ended configuration. The apparatus 300 includes an equalizer stage 310 that includes a CTLE 312 and a PGA 314. Differential inputs INₚ and INₘ for Plus or Positive (P) and Minus or Negative (M) signal components, respectively, are provided as input to the equalizer stage 310. The PGA 314 may include two variable amplifiers 316A and 316B and generates differential amplified outputs at 318A and 318B.

The differential amplified outputs of the PGA 314 are coupled as inputs to pre-driver circuit 320. In one example, the pre-driver circuit 320 includes cascaded inverters 322A and 324A for the P signal path, and cascaded inverters 322B and 324B for the M signal path. The second inverter in each branch (inverter 324A and inverter 324B) has a shorted input to output, forming a load to the first inverter equal to 1/gm. The pre-driver circuit 320 generates differential outputs 326A and 326B that are coupled as inputs to output driver circuit 330.

The output driver circuit 330 may have an open loop class-AB push-pull configuration. For each of the P and M signal paths, the output driver circuit 330 comprises a push-pull configuration of transistors. For example, for the P signal path, transistors 332A and 334A are connected in a push-pull configuration, and the P signal path output (Outₚ) is taken at the sources of transistors 332A and 334A. Similarly, for the M signal path, transistors 332B and 334B are connected in a push-pull configuration, and the M signal path output (Outₘ) is taken at the sources of transistors 332B and 334B.

In one embodiment, as shown in FIG. 3, the outputs of the pre-driver circuit 320 are AC-coupled to the inputs of the output driver circuit 330. That is, capacitors 336A and 338A are connected between the output 326A of the pre-driver circuit 320 and the gates of transistors 332A and 334A, respectively, in the P signal path. Similarly, capacitors 336B and 338B are connected between the output 326B of the pre-driver circuit 320 and the gates of transistors 332B and 334B, respectively, in the M signal path.

The apparatus 300 may further include bias circuitry 340 that generates the DC bias voltages Vₙ and Vₚ to facilitate the AC coupling of the pre-driver circuit 320 to the output driver circuit 330. The bias circuit 340 comprises a first pair of transistors 342A and 344A to generate bias voltage Vₙ, and a second pair of transistors 342B and 344B to generate bias voltage Vₚ.

In the output driver circuit 330, the non-linearity of the n-channel metal oxide semiconductor (NMOS) transistor 332A and of the p-channel MOS (PMOS) transistor 334A cancels each other out because they comprise a source-follower transistor driving another source-follower transistor. The same is true for NMOS transistor 332B and PMOS transistor 334B as well. For a given signal path, there are a minimum number of transistors (2) in the output driver circuit 330 to increase the linear swing with a push-pull action.

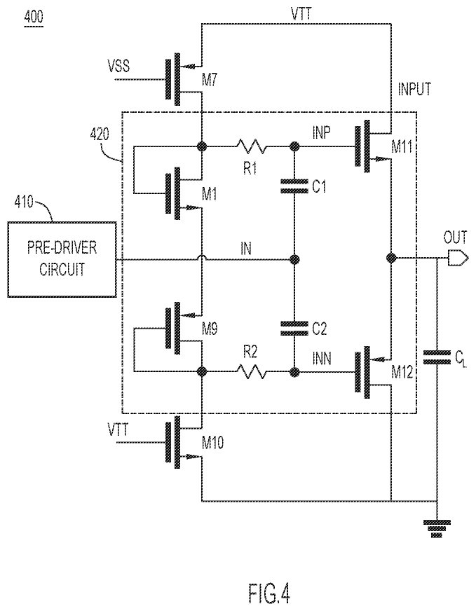

Reference is now made to FIG. 4, which illustrates a schematic diagram of a output driver circuit 400 according to an example embodiment. The output driver circuit 400 is shown for a single-ended (single signal path) output from a pre-driver circuit 410, as an example. However, two instances of such circuits would be used for each of two differential outputs, as depicted in FIG. 3. The output driver circuit 400 has a common-drain class-AB push-pull configuration with AC-coupled inputs from the singled-ended output of the pre-driver circuit 410.

In output driver circuit 400, transistors M11-M1-M9-M12 form translinear loop 420. NMOS transistor M11 and PMOS transistor M12 are connected in a push-pull configuration, where the output of the output driver circuit 400 is at the sources of those transistors. The translinear loop 420 provides an efficient push-pull operation. The capacitive load of the output driver circuit 400 is shown by the capacitor C_{L} that is coupled between the two transistors M11 and M12 and ground. For a SISCAP MZI modulator, the C_{L} may be 2 pF, as an example.

When it is desired to increase the positive voltage on the load, current is pushed into the load from the transistor M11. When it is desired to generate a negative voltage on the load, current is pulled from the load via the transistor M12.

The output of the pre-driver circuit 410 is AC-coupled by capacitors C1 and C2 along with bias transistors M7 and M10 and their associated bias resistors R1 and R2 to drive transistors M11 and M12, respectively, at inputs INP and INN. The AC-coupling capacitors C1 and C2 form a high-pass network.

A single supply voltage can be used for a full chain in the output driver circuit 400. A baseline wander corner is determined by the AC-coupling capacitors C1 and C2. The size of the capacitors is a compromise between baseline wander and high-frequency roll-off.

In summary, the output of the pre-driver circuit 410 is coupled to the output driver circuit 400 without introducing any non-linearity and without any bandwidth limitation because the signal bandwidth is not negatively affected by the capacitances of transistors M1 and M9, due to the resistors R1 and R2 in the circuit. Moreover, the output of the pre-driver circuit 410 is symmetrically coupled to the inputs of the transistors M11 and M12. That is, the input signal (IN) is AC-coupled to two identical RC circuits, R1-C1 and R2-C2. Resistors R1 and R2 have the same resistance values, and capacitors C1 and C2 have the same capacitance values. The AC signal output by the output driver circuit 400 gets superimposed on a DC bias via the push-pull configured transistors M11 and M12.

Simulations of the output driver circuit 400 shown in FIG. 4 indicate that a voltage swing of the output (OUT) of approximately 750 mV can be achieved (for a single-ended output) with 55-65 dB 3rd harmonic suppression. This degree of linearity is excellent and is usually achievable with a negative feedback loop, which is not present in the arrangement shown in FIG. 4. All even order harmonics would be canceled if a complementary (differential) solution is used.

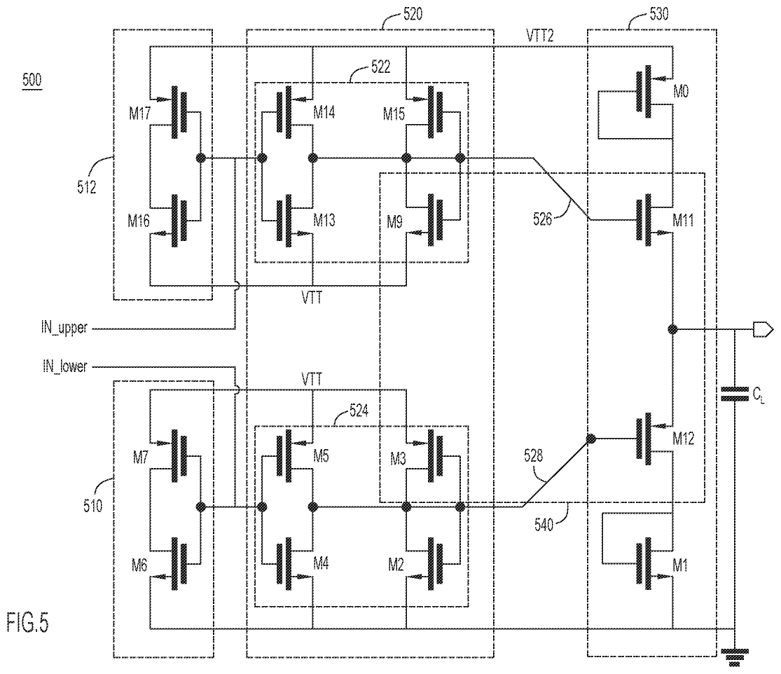

Turning now to FIG. 5, a schematic diagram for another embodiment of a linear driver 500 is shown. This embodiment is an example for a single-ended arrangement. The linear driver 500 includes bias circuits 510 and 512, a pre-driver circuit 520 and a output driver circuit 530. In this embodiment, the outputs of the pre-driver circuits are DC-coupled to the inputs of the output driver circuit 530, as described in more detail below. Furthermore, the pre-driver circuit 520 has two sections. One pre-driver section operates for 0 to VTT and the other pre-driver section operates from VTT to 2VTT. For example, VTT is 1.4V and VTT2 is 2.8V.

Dual supply voltages (VTT, VTT2) are provided for DC bias. The bias circuit 510 comprises transistors M6 and M7 connected in a shorted inverter configuration, and the bias circuit 512 comprises transistors M16 and M17 connected in a shorted inverter configuration. Bias circuits 510 and 512 generate the appropriate bias voltages for all the transistors from the supply voltages VTT and VTT2.

The pre-driver circuit 520 comprises a first pre-driver section 522 consisting of transistors M2, M3, M4 and M5, and a second pre-driver section 524 consisting of transistors M13, M14, M9 and M15. The transistors in the first pre-driver section 522 and the transistors in the second pre-driver section 524 are connected as transconductance/transconductance (gm/gm) pre-drivers. Signals IN_upper and IN_lower from a previous stage (e.g., the equalizer, not shown here) are applied to the first and second pre-driver sections 522 and 524, respectively.

The output driver circuit 530 comprises NMOS transistor M11 and PMOS transistor M12 connected in a push-pull configuration to produce an output (OUT) for a capacitive load C_{L}. Transistors M0 and M1 are provided to prevent voltage overstress on the transistors M11 and M12, respectively, by preventing the gate-to-drain voltage of transistors M11 and M12 from exceeding a limit, such as a 1 V limit.

A translinear loop 540 is formed by transistors M11, M9, M3 and M12. Thus, the translinear loop 540 comprises transistors M3 and M9 in the pre-driver circuit 520 (and in separate pre-driver sections of the pre-driver circuit 520) merged with transistors M11 and M12 in the output driver circuit 530.

The outputs 526 and 528 of the pre-driver sections 522 and 524, respectively, are DC-coupled (directly connected) to the gates of transistors M11 and M12, respectively, in the output driver circuit 530.

The linear driver 500 can operate with higher voltage. When the transconductance (gm) of the pre-driver sections 522 and 524 is high, the output impedance is lower. This results in a higher bandwidth than that of the embodiment shown in FIG. 4, that uses a lower supply voltage. Moreover, the linear driver 500 has no baseline wander corner frequency issues.

Simulations of the linear driver 500 shown in FIG. 5 has shown that the pre-driver stage has a 3^{rd} harmonic of −44 dB, and an output voltage swing of approximately 750 mV. Odd harmonics improve to −55 dB due to non-linearity cancellation in the output driver circuit 530.

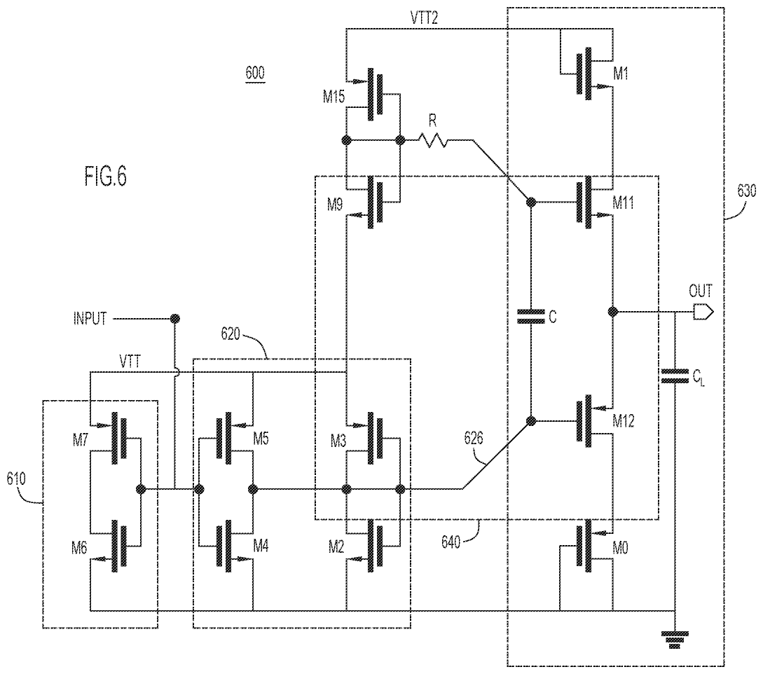

Reference is now made to FIG. 6. FIG. 6 illustrates an embodiment of a linear driver 600 that has a class AB push-pull configuration with asymmetrically-coupled inputs. That is, one side is AC coupled from the pre-driver to the output driver and the other side is DC coupled from pre-driver to output driver, as will be described in more detail below.

The linear driver 600 comprises a bias circuit 610, a pre-driver circuit 620 and a output driver circuit 630. The bias circuit 610 comprises transistors M6 and M7 connected as a shorted inverter. The pre-driver circuit 620 comprises transistors M2, M3, M4 and M5, similar to second pre-driver section 524 shown in FIG. 5. The output driver circuit 630 comprises transistors M11 and M12 connected in a push-pull configuration, and providing an output (OUT) to the capacitive load C_{L}. Transistors M9 and M15 are connected in a shorted-inverter configuration to provide bias voltage. The output of the pre-driver circuit 620 is shown at reference numeral 626.

The pre-driver output 626 is AC-coupled, via capacitor C, to the gate of transistor M11 but directly connected (DC-coupled) to the gate of transistor M12. This is the aforementioned asymmetric inputs to the output driver circuit, where one is by way of a DC-coupling and another is by way of an AC-coupling.

The translinear loop 640 is present in the linear driver 600, and comprises transistors M3, M9, M11 and M12. The translinear loop 640 meshes transistors M11 and M12 in the output driver circuit 630 with transistors M3 in the pre-driver circuit 620. However, in the linear driver 600, the locations of transistors M0 and M1 are interchanged, such that the NMOS transistor M1 is coupled to transistor NMOS transistor M11 and PMOS transistor M2 is coupled to PMOS transistor M12. This arrangement helps to prevent over voltage damage to transistors M11 and M12.

The asymmetric configuration of FIG. 6 helps with baseline wander performance, and also reduces the power consumption from VTT2 (e.g., 2.8V). The DC-coupled input has no low-frequency roll off, while the AC-coupled input has low frequency roll-off. The net output has low-frequency attention of less than 6 dB, which, again, minimizes baseline wander. The output bandwidth drop is due to the capacitive load C_{L} (e.g., 0.7 pF) which may be, for example, 0.7 pF. The pre-driver 3^{rd} harmonic is approximately −44 dB. The odd harmonics of the linear driver 600 improve over that of the pre-driver circuit 620 from −45 dB to −55 dB due to non-linearity cancellation in the output driver circuit 630.

The arrangement of FIG. 6 also allows for using more aggressive values R and C. For example, R=100 kOhms and C=1 pF. The supply currents may be lower, e.g., for VTT2, it may be approximately 24 mA and for VTT, approximately 33 mA.

In one summary, a driver topology is presented to drive a capacitive load, such as a SISCAP-type capacitive load, in a linear fashion. The topology includes a combination of a pre-driver and output driver, the latter of which may also be referred to as an output stage. Several embodiments are presented for the coupling of the push-pull driver with different voltage supply, power, and linearity tradeoffs. An open-loop (meaning without a feedback loop) class-AB push-pull transistor configuration is provided in the output stage to drive the capacitive load. This topology employs a minimum number of transistors (2) in the output stage to increase swing. The inherently linear output stage with NMOS and PMOS transistors cancels out non-linearity of each other. A linear single-ended output swing of ˜750 mV can be achieved with 55-65 dB 3rd harmonic suppression.

In some aspects, the techniques described herein relate to an apparatus including: a pre-driver circuit configured to receive an analog input signal and amplify the analog input signal to generate at an output a pre-driver output signal; and an output driver circuit having an input coupled to the output of the pre-driver circuit, wherein the output driver circuit includes a first transistor and a second transistor connected in a common-drain class-AB push-pull configuration and generates from the pre-driver output signal a driver output signal to drive a capacitive load, wherein the first transistor and the second transistor are part of a translinear loop.

In some aspects, the techniques described herein relate to an apparatus, further including a third transistor and a fourth transistor, a gate and a drain of the third transistor being directly connected to each other, and a gate and a drain of the fourth transistor being directly connected to each other. This relates to the arrangement shown in FIG. 4 where transistors M11 and M12 are the first and second transistors of the class-AV push-pull configuration and transistors M1 and M9 and the third and fourth transistors, respectively.

In some aspects, the techniques described herein relate to an apparatus, further including a first resistor-capacitor circuit connected between the drain of the third transistor and the gate of the first transistor, and a second resistor-capacitor circuit connected between the drain of the fourth transistor and the gate of the second transistor. This is depicted in FIG. 4 with R1 and C1, and R2 and C2.

In some aspects, the techniques described herein relate to an apparatus, further including a first capacitor coupled between the output of the pre-driver circuit and a gate of the first transistor that corresponds to a first input of the output driver circuit, and a second capacitor coupled between the output of the pre-driver circuit and a gate of the second transistor that corresponds to a second input of the output driver circuit. This AC-coupling is depicted in FIG. 3 (for both differential paths) and in FIG. 4 (for a single-ended path).

In some aspects, the techniques described herein relate to an apparatus, wherein the third transistor and the fourth transistor are part of the pre-driver circuit and also form part of the translinear loop. The meshing of the translinear loop between the pre-driver circuit and the output driver circuit is shown in FIG. 5.

In some aspects, the techniques described herein relate to an apparatus, wherein the output of the pre-driver circuit is DC-coupled to the input of the output driver circuit. This DC-coupling is shown in FIG. 5.

In some aspects, the techniques described herein relate to an apparatus, wherein the gate of the third transistor is directly connected to a gate of the first transistor, and the gate of the fourth transistor is directly connected to a gate of the second transistor. This asymmetrical coupling is shown in FIG. 6.

In some aspects, the techniques described herein relate to an apparatus, wherein the pre-driver circuit includes a first pre-driver section and a second pre-driver section, each of the first pre-driver section and the second pre-driver section including a plurality of transistors configured as a transconductance/transconductance pre-driver, wherein the first pre-driver section includes the third transistor and the second pre-driver section includes the fourth transistor. This arrangement is depicted in FIG. 5, where each of the first and second sections of the pre-driver circuit includes a transistor that is part of the translinear loop.

In some aspects, the techniques described herein relate to an apparatus, wherein the output of the pre-driver circuit is AC-coupled to a gate of the first transistor and is DC-coupled to a gate of the second transistor. Again, this asymmetrical coupling is depicted in FIG. 6.

In some aspects, the techniques described herein relate to an apparatus, wherein the fourth transistor is part of the translinear loop, and the gate of the fourth transistor is connected, via a capacitor, to the gate of the first transistor and the gate of the fourth transistor is directly connected to the gate of the second transistor. This arrangement of the translinear loop is depicted in FIG. 6.

In some aspects, the techniques described herein relate to an apparatus including: a pre-driver circuit configured to receive an analog input signal and amplify the analog input signal to generate at an output a pre-driver output signal; and an output driver circuit having an input coupled to the output of the pre-driver circuit, wherein the output driver circuit includes a first transistor and a second transistor connected in a common-drain push-pull configuration and configured to generate from the pre-driver output signal a driver output signal to drive a capacitive load.

In some aspects, the techniques described herein relate to an apparatus, further including a third transistor and a fourth transistor, a gate and a drain of the third transistor being directly connected to each other, and a gate and a drain of the fourth transistor being directly connected to each other, wherein the first transistor, the second transistor, the third transistor and the fourth transistor form a translinear loop.

In some aspects, the techniques described herein relate to an apparatus, further including a first resistor-capacitor circuit connected between the drain of the third transistor and the gate of the first transistor, and a second resistor-capacitor circuit connected between the drain of the fourth transistor and the gate of the second transistor.

In some aspects, the techniques described herein relate to an apparatus, wherein the third transistor and the fourth transistor are part of the pre-driver circuit.

In some aspects, the techniques described herein relate to an apparatus, wherein the gate of the third transistor is directly connected to a gate of the first transistor, and the gate of the fourth transistor is directly connected to a gate of the second transistor.

In some aspects, the techniques described herein relate to an apparatus, wherein the fourth transistor is part of the translinear loop, and the gate of the fourth transistor is connected, via a capacitor, to the gate of the first transistor and the gate of the fourth transistor is directly connected to the gate of the second transistor.

In some aspects, the techniques described herein relate to an apparatus, further including a first capacitor coupled between the output of the pre-driver circuit and a gate of the first transistor that corresponds to a first input of the output driver circuit, and a second capacitor coupled between the output of the pre-driver circuit and a gate of the second transistor that corresponds to a second input of the output driver circuit.

In some aspects, the techniques described herein relate to an apparatus including: a pre-driver circuit configured to receive an analog input signal and amplify the analog input signal to generate at an output a pre-driver output signal; and a output driver circuit including a first transistor and a second transistor connected in a common-drain push-pull configuration, each of the first transistor and the second transistor having a gate that is coupled to the output of the pre-driver circuit, and configured to generate from the pre-driver output signal a driver output signal at an output corresponding to a node connected to a drain of the first transistor and to a drain of the first transistor.

In some aspects, the techniques described herein relate to an apparatus, further including a first capacitor connected between the output of the pre-driver circuit and the gate of the first transistor, and a second capacitor connected between the output of the pre-driver circuit and the gate of the second transistor.

In some aspects, the techniques described herein relate to an apparatus, wherein the pre-driver circuit includes a first pre-driver section and a second pre-driver section, each of the first pre-driver section and the second pre-driver section including a plurality of transistors configured as a transconductance/transconductance pre-driver, wherein an output of the first pre-driver section is directly coupled to the gate of the first transistor and an output of the second pre-driver section is directly coupled to the gate of the second transistor.

In some aspects, the techniques described herein relate to an apparatus, wherein the pre-driver circuit includes a third transistor and a fourth transistor, gate and drain of the third transistor being directly connected to each other, and gate and drain of the fourth transistor being directly connected to each other, and wherein the gate of the fourth transistor is connected, via a capacitor, to the gate of the first transistor and the gate of the fourth transistor is directly connected to the gate of the second transistor.

Embodiments described herein may include one or more networks, which can represent a series of points and/or network elements of interconnected communication paths for receiving and/or transmitting messages (e.g., packets of information) that propagate through the one or more networks. These network elements offer communicative interfaces that facilitate communications between the network elements. A network can include any number of hardware and/or software elements coupled to (and in communication with) each other through a communication medium. Such networks can include, but are not limited to, any local area network (LAN), virtual LAN (VLAN), wide area network (WAN) (e.g., the Internet), software defined WAN (SD-WAN), wireless local area (WLA) access network, wireless wide area (WWA) access network, metropolitan area network (MAN), Intranet, Extranet, virtual private network (VPN), Low Power Network (LPN), Low Power Wide Area Network (LPWAN), Machine to Machine (M2M) network, Internet of Things (IoT) network, Ethernet network/switching system, any other appropriate architecture and/or system that facilitates communications in a network environment, and/or any suitable combination thereof.

Networks through which communications propagate can use any suitable technologies for communications including wireless communications (e.g., 4G/5G/nG, IEEE 802.11 (e.g., Wi-Fi®/Wi-Fi6®), IEEE 802.16 (e.g., Worldwide Interoperability for Microwave Access (WiMAX)), Radio-Frequency Identification (RFID), Near Field Communication (NFC), Bluetooth™, mm.wave, Ultra-Wideband (UWB), etc.), and/or wired communications (e.g., T1 lines, T3 lines, digital subscriber lines (DSL), Ethernet, Fibre Channel, etc.). Generally, any suitable means of communications may be used such as electric, sound, light, infrared, and/or radio to facilitate communications through one or more networks in accordance with embodiments herein. Communications, interactions, operations, etc. as discussed for various embodiments described herein may be performed among entities that may directly or indirectly connected utilizing any algorithms, communication protocols, interfaces, etc. (proprietary and/or non-proprietary) that allow for the exchange of data and/or information.

In various example implementations, any entity or apparatus for various embodiments described herein can encompass network elements (which can include virtualized network elements, functions, etc.) such as, for example, network appliances, forwarders, routers, servers, switches, gateways, bridges, loadbalancers, firewalls, processors, modules, radio receivers/transmitters, or any other suitable device, component, element, or object operable to exchange information that facilitates or otherwise helps to facilitate various operations in a network environment as described for various embodiments herein. Note that with the examples provided herein, interaction may be described in terms of one, two, three, or four entities. However, this has been done for purposes of clarity, simplicity and example only. The examples provided should not limit the scope or inhibit the broad teachings of systems, networks, etc. described herein as potentially applied to a myriad of other architectures.

Communications in a network environment can be referred to herein as ‘messages’, ‘messaging’, ‘signaling’, ‘data’, ‘content’, ‘objects’, ‘requests’, ‘queries’, ‘responses’, ‘replies’, etc. which may be inclusive of packets. As referred to herein and in the claims, the term ‘packet’ may be used in a generic sense to include packets, frames, segments, datagrams, and/or any other generic units that may be used to transmit communications in a network environment. Generally, a packet is a formatted unit of data that can contain control or routing information (e.g., source and destination address, source and destination port, etc.) and data, which is also sometimes referred to as a ‘payload’, ‘data payload’, and variations thereof. In some embodiments, control or routing information, management information, or the like can be included in packet fields, such as within header(s) and/or trailer(s) of packets. Internet Protocol (IP) addresses discussed herein and in the claims can include any IP version 4 (IPv4) and/or IP version 6 (IPv6) addresses.

To the extent that embodiments presented herein relate to the storage of data, the embodiments may employ any number of any conventional or other databases, data stores or storage structures (e.g., files, databases, data structures, data or other repositories, etc.) to store information.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’ nomenclature (e.g., one or more element(s)).

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. An apparatus comprising:
a pre-driver circuit configured to receive an analog input signal and amplify the analog input signal to generate at an output a pre-driver output signal; and
an output driver circuit having an input coupled to the output of the pre-driver circuit, wherein the output driver circuit comprises a first transistor and a second transistor connected in a common-drain class-AB push-pull configuration and generates from the pre-driver output signal a driver output signal to drive a capacitive load, wherein the first transistor and the second transistor are part of a translinear loop.

2. The apparatus of claim 1, further comprising a third transistor and a fourth transistor, a gate and a drain of the third transistor being directly connected to each other, and a gate and a drain of the fourth transistor being directly connected to each other.

3. The apparatus of claim 2, further comprising a first resistor-capacitor circuit connected between the drain of the third transistor and the gate of the first transistor, and a second resistor-capacitor circuit connected between the drain of the fourth transistor and the gate of the second transistor.

4. The apparatus of claim 2, further comprising a first capacitor coupled between the output of the pre-driver circuit and a gate of the first transistor that corresponds to a first input of the output driver circuit, and a second capacitor coupled between the output of the pre-driver circuit and a gate of the second transistor that corresponds to a second input of the output driver circuit.

5. The apparatus of claim 2, wherein the third transistor and the fourth transistor are part of the pre-driver circuit and also form part of the translinear loop.

6. The apparatus of claim 5, wherein the output of the pre-driver circuit is DC-coupled to the input of the output driver circuit.

7. The apparatus of claim 6, wherein the gate of the third transistor is directly connected to a gate of the first transistor, and the gate of the fourth transistor is directly connected to a gate of the second transistor.

8. The apparatus of claim 7, wherein the pre-driver circuit includes a first pre-driver section and a second pre-driver section, each of the first pre-driver section and the second pre-driver section comprising a plurality of transistors configured as a transconductance/transconductance pre-driver, wherein the first pre-driver section includes the third transistor and the second pre-driver section includes the fourth transistor.

9. The apparatus of claim 2, wherein the output of the pre-driver circuit is AC-coupled to a gate of the first transistor and is DC-coupled to a gate of the second transistor.

10. The apparatus of claim 9, wherein the fourth transistor is part of the translinear loop, and the gate of the fourth transistor is connected, via a capacitor, to the gate of the first transistor and the gate of the fourth transistor is directly connected to the gate of the second transistor.

11. An apparatus comprising:
a pre-driver circuit configured to receive an analog input signal and amplify the analog input signal to generate at an output a pre-driver output signal; and
an output driver circuit having an input coupled to the output of the pre-driver circuit, wherein the output driver circuit comprises a first transistor and a second transistor connected in a common-drain push-pull configuration and configured to generate from the pre-driver output signal a driver output signal to drive a capacitive load.

12. The apparatus of claim 11, further comprising a third transistor and a fourth transistor, a gate and a drain of the third transistor being directly connected to each other, and a gate and a drain of the fourth transistor being directly connected to each other, wherein the first transistor, the second transistor, the third transistor and the fourth transistor form a translinear loop.

13. The apparatus of claim 12, further comprising a first resistor-capacitor circuit connected between the drain of the third transistor and the gate of the first transistor, and a second resistor-capacitor circuit connected between the drain of the fourth transistor and the gate of the second transistor.

14. The apparatus of claim 12, wherein the third transistor and the fourth transistor are part of the pre-driver circuit.

15. The apparatus of claim 14, wherein the gate of the third transistor is directly connected to a gate of the first transistor, and the gate of the fourth transistor is directly connected to a gate of the second transistor.

16. The apparatus of claim 12, wherein the fourth transistor is part of the translinear loop, and the gate of the fourth transistor is connected, via a capacitor, to the gate of the first transistor and the gate of the fourth transistor is directly connected to the gate of the second transistor.

17. The apparatus of claim 11, further comprising a first capacitor coupled between the output of the pre-driver circuit and a gate of the first transistor that corresponds to a first input of the output driver circuit, and a second capacitor coupled between the output of the pre-driver circuit and a gate of the second transistor that corresponds to a second input of the output driver circuit.

18. An apparatus comprising:
a pre-driver circuit configured to receive an analog input signal and amplify the analog input signal to generate at an output a pre-driver output signal; and
a output driver circuit comprising a first transistor and a second transistor connected in a common-drain push-pull configuration, each of the first transistor and the second transistor having a gate that is coupled to the output of the pre-driver circuit, and configured to generate from the pre-driver output signal a driver output signal at an output corresponding to a node connected to a drain of the first transistor and to a drain of the first transistor.

19. The apparatus of claim 18, further comprising a first capacitor connected between the output of the pre-driver circuit and the gate of the first transistor, and a second capacitor connected between the output of the pre-driver circuit and the gate of the second transistor.

20. The apparatus of claim 18, wherein the pre-driver circuit includes a first pre-driver section and a second pre-driver section, each of the first pre-driver section and the second pre-driver section comprising a plurality of transistors configured as a transconductance/transconductance pre-driver, wherein an output of the first pre-driver section is directly coupled to the gate of the first transistor and an output of the second pre-driver section is directly coupled to the gate of the second transistor.

21. The apparatus of claim 18, wherein the pre-driver circuit comprises a third transistor and a fourth transistor, a gate and a drain of the third transistor being directly connected to each other, and a gate and a drain of the fourth transistor being directly connected to each other, and wherein the gate of the fourth transistor is connected, via a capacitor, to the gate of the first transistor and the gate of the fourth transistor is directly connected to the gate of the second transistor.
